(19) United States
(12) Patent Application Publication
(10) Pub. No.: US 2006/0145715 A1
(43) Pub. Date: Jul. 6, 2006

(54) Wafer level test head

(76) Inventor: Peter C. Salmon, Mountain View, CA (US)

Correspondence Address: Aldo J. Test;DORSEY & WHITNEY LLP, Suite 3400, 4 Embarcadero Center, San Francisco, CA, 94111, US

(21) Appl. No.: 11/031,219

(22) Filed: Jan. 6, 2005

(51) Int. Cl. G01R 31/02

(52) U.S. Cl. 324/754

(57) ABSTRACT

A test head is described for simultaneous test and/or simultaneous burn-in of all of the chips on a semiconductor wafer, including high powered microprocessor chips. A test execution wafer is attached to a test pedestal with connections for power plus an interface to a test support computer. Mounted on the test execution wafer are all of the IC chips required to implement test circuits, power distribution, local memory, temperature sensing, and communication interfaces. Advanced flip chip connectors are preferably employed for assembling the test execution wafer; they enable rework of any chips that prove defective. Embedded in the test execution wafer are general purpose interconnection circuits plus through-wafer connectors. A test socket employing wells filled with liquid metal is provided on the back side of the test execution wafer. The wafer under test is bumped at the I/O pads, and the bumps are inserted into the wells filled with liquid metal. By circulating water or other cooling fluid against the back side of the wafer under test, a cooling rate of 20,000 watts or more can be applied.

This invention relates to apparatus and methods for testing electronic components, and more particularly to apparatus and methods for simultaneous testing of all the die on a wafer, including high powered microprocessors.

### BACKGROUND OF THE INVENTION

The current practice for testing integrated circuit (IC) chips and the systems using them includes wafer sort at the wafer level, class test at the packaged component level, board test at the board level, and system test at the system level. At wafer sort, typically the wafer is tested one chip at a time, using a probe card that steps in sequence across the wafer. The probes typically have inductance that limits the speed of wafer sort testing. Around 10-20% of the total chips are typically defective at wafer sort. The remaining good chips are assembled into discrete packages and class tested, typically at full clock speed. If burn-in is required it is usually performed using packaged parts; they are plugged into sockets on burn-in boards and exercised at temperature and voltage extremes to weed out weak chips that may fail prematurely. Packaged parts that survive class test and burn-in are assembled onto printed circuit boards (PCBs), and the boards are verified using a board level test. If components prove defective at board test, they may be replaceable using rework procedures; typically this includes melting of the soldered connections so that the defective part can be withdrawn from the board. If the board fails at system test it may be replaced, or repaired by returning to the board level test.

The current invention addresses test apparatus and methods to achieve known good die (KGD), for the case of testing all of the chips on a wafer simultaneously. Both test throughput and test cost improve by a factor roughly equal to the number of good die on a wafer. A 300 mm wafer may typically contain 177 microprocessor chips measuring 18 mm on a side; at 90% yield 159 chips will be functional. For logic circuits like microprocessors having a large number of leads (up to several thousand per chip), if a probe card is used it will be extremely complex. Also, the test environment will require massive parallelism in the test circuits. If the logic chips dissipate a lot of power (120 watts is common for microprocessor chips), then large amounts of heat must be dissipated to prevent melting or burning of the test head. The total heat dissipated for a parallel wafer test of microprocessor chips can be over 20,000 watts, too much for any test heads in current use.

Insertion force is another critical parameter for wafer level testing. For the case of 177 microprocessor chips, each having 2,000 input/output pads, the total number of connections required is 354,000. If each connector requires 10 grams of insertion force for example, the total required force is 3,540 kilograms. The current invention addresses this problem by providing connectors that include liquid filled wells, each requiring almost zero insertion force.

### SUMMARY OF THE INVENTION

The current invention is a test head that can be used for parallel testing and/or burn-in of a wafer full of high-powered logic chips such as microprocessors. A test pedestal includes connections to a power source and a test support computer. Test circuits are mounted on a test execution wafer supported on the test pedestal, connected to the power source and the test support computer. The preferred method for mounting chips on the test execution wafer employs an advanced flip chip connector. Each connector includes a copper spring element inserted into a well filled with solder; the spring elements attach to input/output (I/O) pads of attached chips, and the wells filled with solder connect with interconnection traces provided on the test execution wafer. The spring elements have a length to diameter ratio that provides flexural behavior in the horizontal plane, useful for relieving shear stresses. The springs are preferably wire-like with a bend in the middle; the bend enables flexibility for relieving tensile/compressive stresses in the vertical direction. Although the test execution wafer is preferably a silicon wafer and many of the attached chips may also be fabricated in silicon, a generalized assembly method that can tolerate mismatched expansion characteristics is preferred.

IC chips mounted on the test execution wafer implement most of the test functions except for some high level functions that are preferably implemented on a test support computer. The test execution wafer also requires through-wafer interconnects for routing test signals using short path lengths, enabling high speed control and sensing of circuits on the wafer under test. It preferably also contains all of the power distribution circuits required for distributing power locally to each die on the wafer under test. The advanced flip chip connectors enable replacement of any assembled chips that prove to be defective. Even if 100 or more IC chips are required to implement all of the required test functions, the rework capability allows such a complex assembly to be cost-effectively produced. Each chip can be regarded as a plug-in component that can be tested and replaced as required to achieve 100% assembly yield.

The back side of the test execution wafer includes test socket terminals comprising wells filled with liquid metal; the wells accept bumped terminals of the wafer under test. Bumps are provided as terminals at each input/output (I/O) pad of the wafer under test. Multiple bump types can be accommodated, including solder bumps, copper mesas, and copper spring elements. The bumps are aligned with corresponding wells on the test execution wafer and are inserted into liquid metal in the wells; this creates a temporary connection for the duration of the test. The method of aligning the two wafers typically employs split beam optics having alignment accuracy as good as ±1 μm, as is known in the art. Details of the test socket are described in co-pending U.S. patent application Ser. No. 60/617,716.

For testing wafers that contain high-powered chips, a cooling chamber is provided that mates with the test pedestal, including an O-ring seal around the periphery of the wafer under test. Water is circulated in the cooling chamber during testing; it is in direct contact with the back side of the wafer under test and provides a low impedance cooling path, capable of cooling the wafer at a rate of 20,000 watts or more. If burn-in is required, it is preferably conducted using the same setup, providing the desired temperature by controlling the flow of cooling water, and also providing the required variations in power supply voltages. The set of locations of chips that pass all tests is recorded in local memory, and up-loaded to the test support computer, which is preferably manned by a test operator.

At the completion of testing, water is evacuated from the cooling chamber, the chamber is removed from the test pedestal, the back side of the wafer under test is dried with a jet of air, and the wafer under test is removed by withdrawing the bumps from the wells. The wafer under test can then be diced and the known good die (KGD) plated in waffle packs or the like in preparation for the next assembly step. Confidence in the KGD tested by this method is greater than previously achievable, because the wafer level tests have been conducted at full speed and full power.

There are typically at least 150 good die per 300 mm wafer, even for relatively large sized microprocessor chips. If they are tested in parallel rather than serially, the resulting test throughput will be approximately 150 times greater. The value of such a tester is approximately 150 times greater than a traditional serial tester. Additional economies derive from the improved confidence (yield) of KGD tested using the current invention. This level of parallelism and test throughput provides a reference case for the current invention, including provisions for handling 20,000 watts or more of heat generated during testing.

Much of the hardware complexity in a modern integrated circuit tester relates to the “pin electronics”; i.e., the drivers and relays and sense circuits connecting a tester node to a node under test. It has been difficult to achieve high speed control and sensing with current test heads because of the physical path length between these nodes, typically including a probe card to provide the necessary mapping of tester connections. In the preferred embodiment of the current invention these path lengths are shorter, resulting in less power required in the driver circuits and easier testing at higher bit rates. This requires development of a custom test execution wafer for each different chip design; it has well locations that are matched to the particular layout of bump terminals. This represents “hard-wired” connectivity in the test execution wafer rather than in a probe card.

### BRIEF DESCRIPTION OF THE DRAWINGS

The foregoing and other objects of the invention will be more clearly understood from the accompanying drawings and description of the invention:

FIGS. 1A-1E illustrates in schematic cross-section a sequence of steps to configure and operate a test head of the current invention;

FIG. 2A shows the topside of a test execution wafer, including 177 microprocessor sites;

FIG. 2B is an expanded view of one of the microprocessor sites of FIG. 2A, showing a test socket comprising an array of wells filled with conductive material;

FIG. 3A shows the bottom side of the test execution wafer of FIG. 2A, showing sites for test clusters, a test controller chip, and a local memory chip;

FIG. 3B is an expanded view of one of the test cluster sites of FIG. 3A, showing a master test chip, a collection of slave test chips, a power distribution chip, and a cluster interface chip;

FIG. 4 is a flow diagram showing control paths linking all of the major objects of the proposed test system;

FIGS. 5A-5F illustrates in cross-section a set of structures and process steps relating to a preferred flip chip attachment for components attached to the test execution wafer.

FIGS. 6 illustrates in cross-section a preferred structure for interconnection circuits and through wafer interconnects in a test execution wafer; and

FIGS. 7A-7C shows in cross-section several alternative bump types for the wafer under test.

### DETAILED DESCRIPTION OF THE PREFERRED EMBODIMENTS

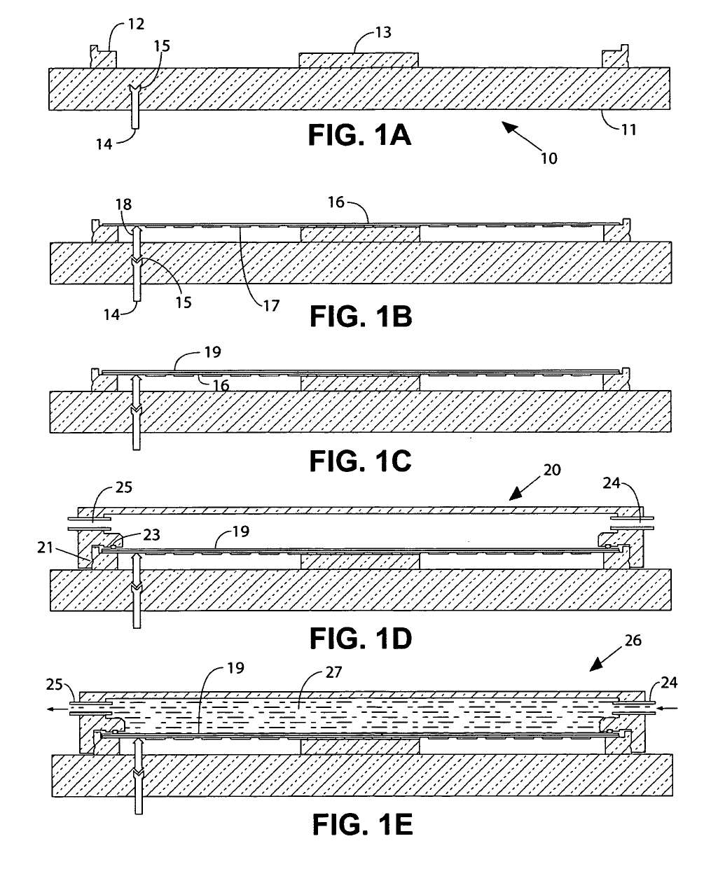

FIG. 1A-1E details a sequence of steps to configure and operate a wafer level test head of the current invention. The reference case will be assumed: 177 microprocessor die on a bumped 300 mm wafer, with each die dissipating 120 watts of heat. The total heat generated during testing is over 20,000 watts.

FIG. 1A shows a test pedestal 10 including a base plate 11, a support ring 12, a center support 13, and electrical input/outputs 14 terminating in a connector 15. Electrical input/outputs 14 include a power source such as 42 volts DC, plus an interface to a test support computer, as will be further described.

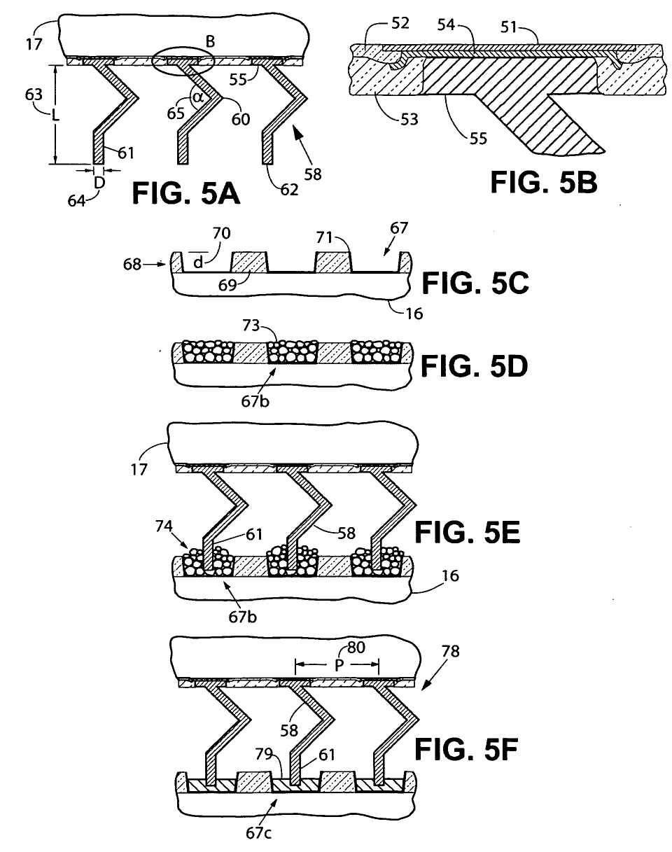

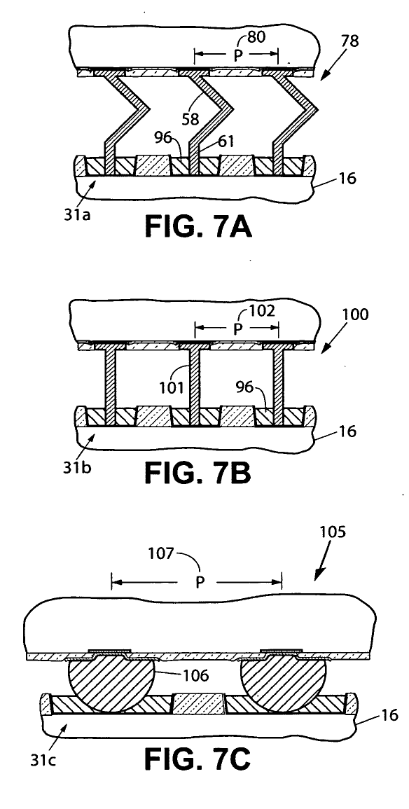

In FIG. 1B test execution wafer 16 is positioned on pedestal 10 using support ring 12 and center support 13. Test execution wafer 16 has an array of integrated circuit (IC) chips like 17 mounted on its bottom side. These chips will perform all test execution and power distribution functions, as will be further described. They are attached using improved flip chip connectors that allow replacement of any chips that prove defective, as will be further described in reference to FIG. 5A-5F. Electrical feeds 18 take the power and signals available at connector 15, and connect them to test execution wafer 16, using soldered leads for example. Test execution wafer 16 has a test socket on its top side, including an array of wells filled with liquid metal. The wells are shaped to accept a corresponding array of bumps on the wafer under test, to be further described in reference to FIG. 7A-7C.

In FIG. 1C a wafer to be tested 19 has been aligned to the test execution wafer, and its bumps have been inserted into the wells filled with liquid metal, to be described. Flip chip assembly stations having split beam optics are known in the art and can achieve alignment accuracies as good as ±1 μm; they can be adapted for the larger wafer size of the current invention.

In FIG. 1D a cooling enclosure 20 has been attached to pedestal 10, using an interference fit 21. The attachment includes a liquid seal at the periphery of wafer under test 19, using compressed O-ring 23 as shown. Inlets 24 and outlets 25 are provided for circulating a cooling fluid, to be described.

FIG. 1E shows a completed test head of the current invention 26, including cooling fluid 27 circulating in the cooling enclosure. Fluid 27 may be water for example, or any other suitable coolant. Fluid 27 is circulated for the duration of testing, while power is applied to the wafer under test. Since water has a specific heat of 4.186 Joules per gram per degree Centigrade, a flow rate of 5 liters per minute will provide over 20,000 watts of cooling if the water temperature rises by 60° C. Note that the cooling fluid is well coupled to the wafer under test, by circulating directly against its surface. If burn-in is desired, the flow rate may be adjusted to achieve a desired burn-in temperature, and the power distribution devices may also be controlled to deliver the required burn-in supply voltages.

After the wafer test is complete, test results stored in local memory are transmitted to the test support computer using electrical input/outputs 14 and 18. Cooling fluid 27 is pumped out of cooling chamber 20. The wafer under test 19 is dried using a jet of compressed air for example, and removed by withdrawing the bumps from the wells. It can then be diced, and the good die can be placed in waffle packs for example, ready for the next assembly operation.

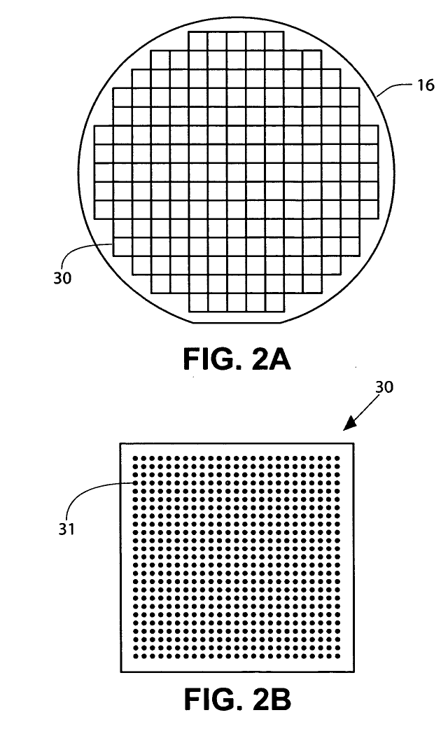

FIG. 2A shows the top surface of test execution wafer 16, including 177 socket arrays 30, corresponding to 177 microprocessor die on the wafer to be tested.

FIG. 2B is an expanded view of socket array 30, showing an array of wells 31; each well preferably filled with liquid metal, to be further described.

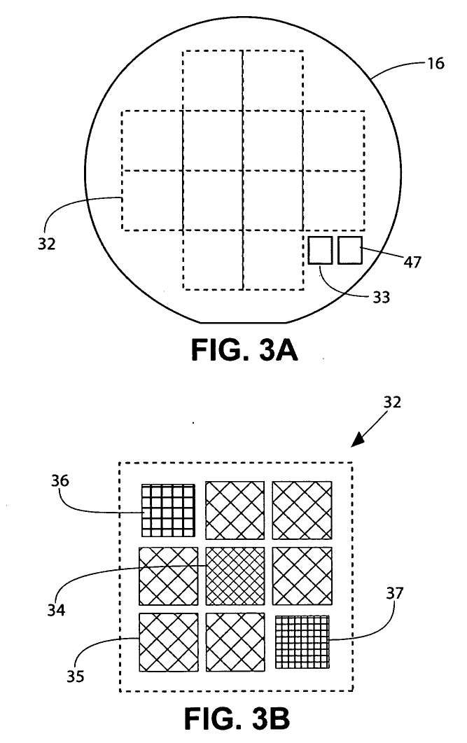

FIG. 3A depicts the bottom side of test execution wafer 16, including multiple locations 32 of a test cluster, to be defined in FIG. 3B. Also included is a test controller chip 33, which interfaces between the test support computer and each test cluster 32, to be further described. Test controller chip 33 accesses local memory chip 47 for buffering test inputs and outputs that flow between test clusters 32 and the test support computer, to be further described.

FIG. 3B shows an expansion of test cluster 32, including master chip 34, multiple slave chips 35, a power distribution chip 36, and a cluster interface chip 37. Master chip 34 provides test vectors to slave chips 35 which provide test input/output functions (pin electronics) for the large number of inputs and outputs associated with the circuits on the wafer under test. The pin electronics typically includes registers for holding test vectors and test results, and comparators for comparing each bit within a test vector against a corresponding bit containing a known good value. Power distribution chip 36 is digitally controlled; it accepts commands from master chip 34 and meters local power supply voltages that vary as required for the various tests, perhaps including burn-in. Cluster interface chip 37 interfaces master chip 34 in each test cluster to test controller chip 33 at the wafer level; it also preferably includes temperature sensing circuits, for localized temperature monitoring of the circuits under test.

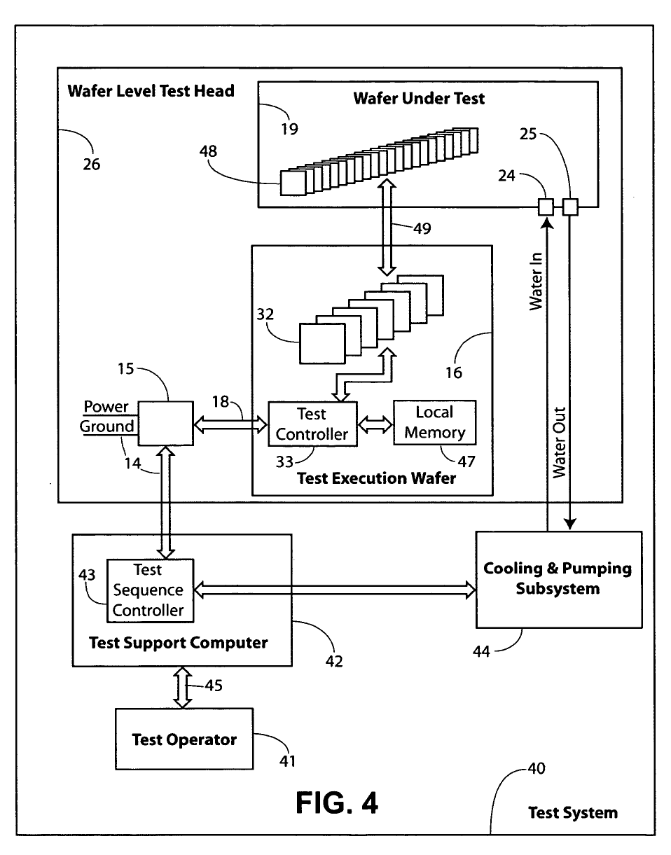

FIG. 4 is a control flow diagram encompassing all of the elements of test system 40, including test operator 41, test support computer 42, test sequence control 43, pumping system 44 and wafer level test head 26. Operator 41 communicates with test support computer 42 via human interface 45 as is known in the art, typically including a keyboard and a display monitor. Test sequence controller 43 provides sequencing for starting and stopping the test, pausing for data transfers if required, and also controls cooling and pumping system 44. Test sequence controller 43 communicates via input/outputs 14 of FIG. 1, connector 15, and electrical feeds 18 with test controller 33 on the test execution wafer. Test controller 33 accesses local memory 47 and interfaces with test clusters 32 as shown. As previously described, test clusters 32 contain all of the drivers and receivers for testing all of the die 48 on wafer under test 19 simultaneously; this interface is shown as 49. Pumping system 44 delivers cooling fluid at inlet 24 of FIG. 1 and exhausts the fluid at outlet 25 as shown, with a flow rate controlled by test sequence controller 43. The test architecture described is just one example of many possible implementations of the proposed method; it is intended to show a practical and cost-effective implementation of a wafer level tester that can meet the dual challenges of full speed testing at gigabit per second rates, while controlling and dissipating power levels of 20,000 watts or more.

Assembly using flip chip connectors is critical to the size constraint of fitting all of the necessary test electronics on a single wafer, as well as the performance goal of gigabit per second signaling rates. Conventional flip chip attachments using solder ball bumps are a less attractive solution because of difficulty performing rework, a necessary activity for achieving the goal of 100% assembly yield for test execution wafer 16. Also, solder ball bumps typically require a larger pitch, as will be further described, and also have a larger inductance than the bumps of the preferred connectors.

FIG. 5A shows semiconductor chip 17 of FIG. 1 having flip chip bumps in the form of conductive spring elements 58. Area B of FIG. 5A is shown expanded in FIG. 5B. Together, FIG. 5A and FIG. 5B show a semiconductor substrate 17 having input/output pads 51 showing through openings in a passivation layer 52. An under bump metallization (UBM) 54 covers each pad. A preferred sequence of under bump layers is a titanium adhesion layer followed by a seed layer of copper; a typical thickness for both layers is 50-80 nm. Conductive copper spring elements 58 are built up from the copper seed layer of UBM 54, as described in co-pending U.S. patent application Ser. No. 11/015,213. Spring elements 58 preferably include a base pad 55 that provides a strong attachment to input/output pads 51, a bend 60 that enables spring-like behavior and an end or terminus 61 that is typically perpendicular to I/O pad 51. Since copper is a ductile material, spring elements 58 can be readily deformed without breaking or cracking, with end 62 moving as required relative to base pad 55. To avoid cracking of the spring element due to fatigue caused by repetitive bending cycles, copper deformation should be limited to its elastic range only. If lateral displacements of the ends 62 of spring elements 58 can occur at low applied force, this will have the effect of relaxing shear stresses in the horizontal plane. The deflection force depends on the flexibility of the spring element. For lateral deflections in the horizontal plane, flexibility of spring element 58 depends on its length L, 63 and its diameter D, 64. A suitable range for length is 50-250 μm and a suitable range for diameter is 5-50 μm. The preferred length and diameter are 100 μm and 10 μm respectively. In addition, length 63 of spring element 58 will change when bend angle α, 65 changes, and this can be used to relax stress in the vertical direction, normal to I/O pad 51. Vertical flexibility of the spring element depends on the size and angle of the “sideways V” portion of the spring element and on the diameter: bigger sizes, smaller angles and smaller diameters will increase flexibility. By providing stress relief using the flexural behavior of the spring elements, an epoxy under layer is avoided and a serious impediment to rework is eliminated.

FIG. 5C shows test execution wafer 16 having wells 67 fabricated in assembly layer 68 formed from dielectric material 69 such as benzo cyclo butene (BCB). The BCB is preferably photo-defined, by exposing with ultra-violet radiation through a mask as is known in the art. A suitable depth d, 70 for the wells is 10-30 μm with 15 μm preferred. Wells 67 have conductive walls 71 providing the functions of a UBM; the conductive walls also connect with traces in substrate 16, as will be further described. The conductive walls are preferably formed from sputtered titanium/copper for adhesion, followed by 2-5 μm of electroplated nickel. The nickel provides a diffusion barrier and a solder-wettable surface.

In FIG. 5D, a fine-grained solder paste 73 has been deposited in the wells, preferably using a squeegee to press the paste into the wells. A well filled with solder paste is labeled 67b. A preferred solder paste is 88Au12Ge with a melting point of 356° C.; this paste does not contain toxic lead and its high melting point makes for a robust assembly in a high-power environment.

FIG. 5E shows the effect of aligning IC chip 17 with test execution wafer 16, and inserting the bumps (conductive spring elements 58) into the wells. A preferred alignment method employs split beam optics, achieving alignment accuracy as good as ±1 μm, as is known in the art. Insertion of the bumps in the wells is a gentle process because the solder paste is soft, the wells are deep, and the spring elements are flexible in the vertical direction; thus breakage or damage of semiconductor parts can be avoided. This is particularly important for recent IC chips that employ fragile low-k dielectrics. As end section 61 of spring element 58 penetrates well filled with solder 67b, some solder material 74 is displaced upward as shown.

FIG. 5F shows completed flip chip attachments 78 of the current invention, including spring elements 58 inserted into wells filled with solder 67c, after heating to create reflowed solder 79. The volume of solder paste typically reduces to approximately one half during reflow. The melted solder solidifies around end section 61 of the spring structure, providing a strong mechanical attachment. Flip chip connector 78 has low-electrical resistance, small size compared with solder ball connectors, and low inductance because of the small size. The minimum pitch P, 80 between connectors is around 80 μm, fine enough to handle all anticipated pitches of bonding pads on a wafer under test. Connector 78 has a compliant structure that relieves mechanical stress and allows the elements it connects to remain flat. Additionally, good electrical and mechanical connection can be achieved over a range of insertion depths of spring elements 58 in wells filled with solder 67c. Using a preferred well depth of 15 μm, variations of around 5 μm penetration depth are acceptable. A larger range of adjustability can be provided if necessary, using deeper wells. Vertical compliance helps to avoid problems arising from imperfectly thinned or planarized wafers. This vertical adjustability contrasts with the planarity problems associated with solder ball connections; lacking compliant elements the solder balls require a diameter accuracy of around ±1 μm to achieve adequate planarity for reliable connections.

A critical attribute of flip chip connectors 78 is the ability to rework an attachment if the assembled component proves to be defective; it is this capability that enables 100% assembly yield for the test execution wafer, despite the large number of attached chips. Rework of an assembly employing flip chip connectors 78 will now be described. The substrate is pre-heated on a hot plate to a temperature below the solder melting point. Hot gas is directed at the defective chip (and not at its neighbors) using a shrouded source of hot inert gas. When the solder melts in the wells, the bumps are withdrawn and the defective component is discarded. Preferably the remaining solder in the wells is sucked out in one quick operation. The wells are refilled with fresh solder paste, using a miniature squeegee if space is limited. After inspection and any necessary touch-up, a replacement part is assembled. There are no fragile leads on the substrate that can be damaged during this rework operation, and it can be performed as many times as necessary.

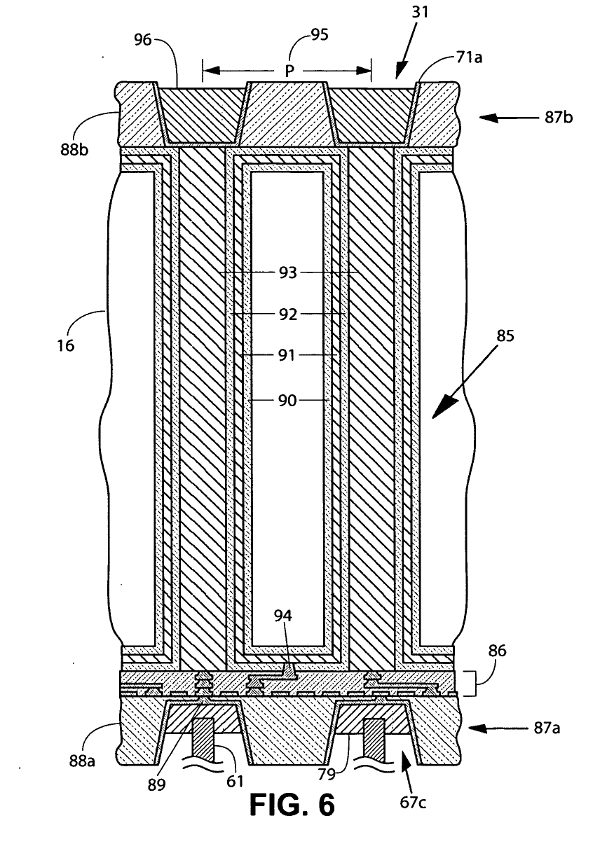

FIG. 6 shows a preferred method for providing through wafer interconnects for wafer 16 of FIG. 1, using polysilicon feedthroughs 85. This method follows the work of Eugene M. Chow et al, “Process Compatible Polysilicon-Based Electrical Through-Wafer Interconnects in Silicon Substrates”, Journal of Micro-electro-mechanical Systems, Vol. 11, No. 6, December 2002. The process has been developed for polysilicon pillars having a diameter of 20 μm in a wafer 400 μm thick. As discussed in reference to FIG. 1, test execution wafer 16 has attached chips at its bottom surface and wells providing a test socket at its top surface. Multilayer interconnection circuits 86 are provided in order to map between dissimilar pin-out patterns at the top and the bottom wafer surfaces. After interconnection circuits 86 have been fabricated, assembly layer 87a is fabricated as shown, using photo-defined BCB 88a as is known in the art. Reflowed solder 79 in wells 67c from FIG. 5F binds the ends 61 of the preferred flip chip connectors 78 that are provided on all of the attached IC chips. Polysilicon feedthrough 85 includes a first isolation layer 90 of silicon dioxide, a screen layer 91 of deposited polysilicon, a second isolation layer 92 of silicon dioxide, and a polysilicon through connect 93 as shown. Each feedthrough 85 has a typical resistance of 10-14 ohms and typical capacitance of 1 picofarad, enabling high speed signaling through the wafer. For high current signals and for power supplies, multiple feedthroughs can be used in parallel. Screen 91 is typically connected to ground using a via like 94. At the top of the wafer, conductive walls 71 a typically comprise a layer of aluminum that bonds with the exposed polysilicon pillar 93 followed by sputtered titanium/copper and plated nickel. Wells 31 from FIG. 2B are filled with a conductive fluid or paste 96; preferably a liquid metal like an alloy of gallium. Suitable alloys may include indium to lower the melting point, antimony to reduce oxidation, and bismuth to improve fluidity. The pitch of wells 31 will depend on the type of flip chip bump used on the wafer under test, as will be further discussed. However, the minimum pitch P, 95 may be as small as around 8011m.

The embedded circuits in test execution wafer 16 are preferably passive, used for interconnection purposes. Required active circuits are preferably contained in attached IC chips. By not implementing active circuits in test execution wafer 16, fewer masking steps will be required and the wafer can be fabricated relatively inexpensively, potentially on older fabrication lines.

FIG. 7A-7C illustrates the use of different kinds of bumps on the wafer under test. In FIG. 7A flip chip connectors 78 include conductive spring elements 58 as shown, with a minimum pitch 80 of around 80 μm. In FIG. 7B, flip chip connectors 100 include wire-like mesa elements 101; these may be used if the connected substrates are the same or similar, thus reducing the need for compliance to relieve mechanical stresses. Connectors 100 may be fabricated using a similar wafer level process as is used to electroform spring elements 58. They also have a minimum pitch 102 of around 80 μm. FIG. 7C shows flip chip connectors 105 that use solder bumps 106. The minimum diameter of such bumps is typically around 100 μm, leading to a minimum pitch 107 of 150-200 μm. Thus wells 31c have to be larger in diameter than wells 31a and 31b of FIG.7A and FIG. 7B.

What is claimed is:

1. A test head for test or burn-in of semiconductor wafers comprising:
a test pedestal having connections to a power source and a test support computer;
a test execution wafer mounted on said test pedestal and connected to said power source and to said test support computer;
said test execution wafer including both mounted integrated circuit chips and embedded circuits for executing test functions and/or burn-in;
said test execution wafer also including a socket for connecting to a wafer under test; and,
said socket comprises an array of wells filled with a conductive fluid or paste.

2. The test head of claim 1 wherein said conductive fluid or paste is a liquid metal.

3. The test head of claim 1 and including a cooling chamber that attaches to said test pedestal.

4. The test head of claim 3 and including means for circulating a cooling fluid through said cooling chamber.

5. The test head of claim 1 wherein said circuits for executing said test or said burn-in include registers and comparators and digitally controlled power distribution devices.

6. The test head of claim 1 wherein said circuits for executing said test or said burn-in include test controllers, communication interfaces, local memory, and temperature sensors.

7. A method for simultaneously testing all of the die on a semiconductor wafer under test comprising the steps of;
a) providing a test execution wafer having attached integrated circuit chips containing test circuits;
b) providing a multi-pin connector between said test execution wafer and said wafer under test;
c) attaching said semiconductor wafer under test to said test execution wafer using said multi-pin connector;
d) simultaneously testing all of said integrated circuit chips on said semiconductor wafer using said test circuits, and recording the test results; and,
e) communicating said test results to a test operator.

8. The method of claim 7 wherein said each of said pins of said connector comprises a conductive bump inserted into a well filled with a conductive fluid or paste.

9. The method of claim 7 wherein said test circuits include circuits for metering and distributing power.

10. The method of claim 7 and including the step of providing a circulating coolant fluid in contact with said semiconductor wafer under test.

11. The method of claim 7 and including the step of simultaneous burn-in of all of said die on said wafer under test, said burn-in step including the adjustment of operating temperature and voltage.

12. A test system for testing and/or burning-in semiconductor wafers comprising:
a test support computer including a test controller, said test support computer under control of a test operator;
a test head for accepting said semiconductor wafers, said test head in communication with said test controller; and,
wherein said test head includes a test socket comprising wells filled with a conductive fluid or paste.

13. A test system for testing and/or burning-in semiconductor wafers comprising:
a test support computer including a test controller, said test support computer under control of a test operator;
a subsystem for cooling and circulating coolant, under control of said test controller;
a test head for accepting said semiconductor wafers, said test head in communication with said test controller; and,
wherein said test head includes test execution circuits and test support circuits, a test socket comprising wells filled with a conductive fluid or paste, and a chamber for circulating said coolant fluid.

14. The test systems of claim 12 and 13 wherein said conductive fluid or paste is a liquid metal.

15. In a test head for testing and/or burning-in semiconductor wafers, a test execution wafer including both mounted integrated circuit chips and embedded circuits for executing test functions; and,
a socket comprising an array of wells filled with conductive fluid or paste for detachably connecting to a wafer under test.

16. A test execution wafer as in claim 15 wherein said conductive fluid is a metal.
